(19) United States
(12) Patent Application Publication
(10) Pub. No.: US 2012/0248585 A1
(43) Pub. Date: Oct. 4, 2012

(54) ELECTROMAGNETIC INTERFERENCE SHIELDING STRUCTURE FOR INTEGRATED CIRCUIT SUBSTRATE AND METHOD FOR FABRICATING THE SAME

(75) Inventor: MING-CHE WU, NANTOU COUNTY (TW)

(73) Assignees: UNIVERSAL GLOBAL SCIENTIFIC INDUSTRIAL CO., LTD., NANTOU COUNTY (TW); UNIVERSAL SCIENTIFIC INDUSTRIAL (SHANGHAI) CO., LTD., SHANGHAI (CN)

(21) Appl. No.: 13/099,559

(22) Filed: May 3, 2011

(30) Foreign Application Priority Data
Mar. 28, 2011 (TW) 100110566

(51) Int. Cl. H01L 23/552; H01L 21/768

(52) U.S. Cl. 257/659; 438/612; 257/E23.114; 257/E21.575

(57) ABSTRACT

An electromagnetic interference (EMI) shielding structure for integrated circuit (IC) substrate includes a plurality of conductive contacts, a covering layer, and a sputtered layer. The conductive contacts are formed at the perimeter of a chip area on the IC substrate. The covering layer is formed on the conductive contacts and covers the chip area. A groove is formed on the covering layer for exposing the conductive contacts. The sputtered layer is formed on the covering layer and connected to the conductive contacts. The EMI shielding structure can restrain the interference in the chip area.

### BACKGROUND OF THE INVENTION

1. Field of the Invention

The instant disclosure relates to an electromagnetic interference (EMI) shielding structure; more particularly, to an EMI shielding structure for the integrated circuit (IC) substrate and method for fabricating the same.

2. Description of Related Art

In today's market, electronic devices are becoming smaller in size. Such trend often leads to the over-population of electronic parts and circuitries in a confined space. In effect, this increases the opportunities of circuit disturbances, in which the electromagnetic interference (EMI) and noise interference are the most troublesome issues. The causes of EMI are very diverse with many factors. The issue of addressing EMI has long been a major emphasis in the design and qualification of electronic devices.

There are mainly two types of EMI, namely the radiated and conducted type. Radiated EMI can radiate across open space without any physical contact. In response, shielding and grounding means are often employed to reduce the EMI. For example, conductive casing can be used around the electronic circuits to provide a shielding effect in guarding against the EMI. However, the inclusion of shielding structure increases the size of the electronic device, which is undesirable. Furthermore, to reduce the effect of EMI on a particular module, such as the radio frequency (RF) module, the installment of the shielding layer would be structurally complicated with added expense. Meanwhile, the conducted EMI is caused by the physical contact of the conductors. Hence, EMI generated by an electrical circuit can interfere other electronic module if both are connected in the same electrical system, and vice versa.

### SUMMARY OF THE INVENTION

The instant disclosure provides an EMI shielding structure for an IC substrate, wherein a sputtering method is used to form separated areas directly on the IC substrate. The disclosed EMI shielding structure has miniaturized characteristics and is cost effective.

The IC substrate has a chip area. The EMI shielding structure comprises a plurality of conductive contacts, a covering layer, and a sputtered layer. The conductive contacts are formed on the perimeter of the chip area. The covering layer is formed on the conductive contacts and covers the chip area. A groove is formed on the covering layer for exposing the conductive contacts. The sputtered layer is formed on the covering layer and connected to the conductive contacts.

The instant disclosure also provides a fabrication method of the EMI shielding structure. The method includes the following steps: forming at least one conductive contact on the perimeter of a chip area; forming a covering layer over the chip area and the conductive contacts; forming a groove on the covering layer to expose the conductive contacts; and forming a sputtered layer on the covering layer and connecting to the conductive contacts in covering the chip area.

To summarize, the instant disclosure utilizes the sputtering technique in forming the EMI shielding structure to restrain the EMI of the internal circuit. The disclosed EMI shielding structure has miniaturized characteristics and is cost effective.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is a top view of an EMI shielding structure for a first embodiment of the instant disclosure.

FIG. 2 is a schematic view of the EMI shielding structure 123 for the first embodiment of the instant disclosure.

FIG. 3 is a schematic view of fabricating the EMI shielding structure for the first embodiment of the instant disclosure.

FIG. 4 is a schematic view of fabricating an EMI shielding structure for a second embodiment of the instant disclosure.

FIG. 5 is a schematic view of fabricating an EMI shielding structure for a third embodiment of the instant disclosure.

FIG. 6 is a schematic view of fabricating an EMI shielding structure for a fourth embodiment of the instant disclosure.

FIG. 7 is a schematic view of an EMI shielding structure for a fifth embodiment of the instant disclosure.

FIG. 8 is a schematic view of an EMI shielding structure for a sixth embodiment of the instant disclosure.

FIG. 9 is a flow diagram for fabricating method of an EMI shielding structure for an IC substrate of a seventh embodiment of the instant disclosure.

### DETAILED DESCRIPTION OF PREFERRED EMBODIMENTS

In the paragraphs below, figures will be referenced to explain different embodiments of the instant disclosure in details. For identical parts, same numbers are used in different figures for illustrations.

### First Embodiment

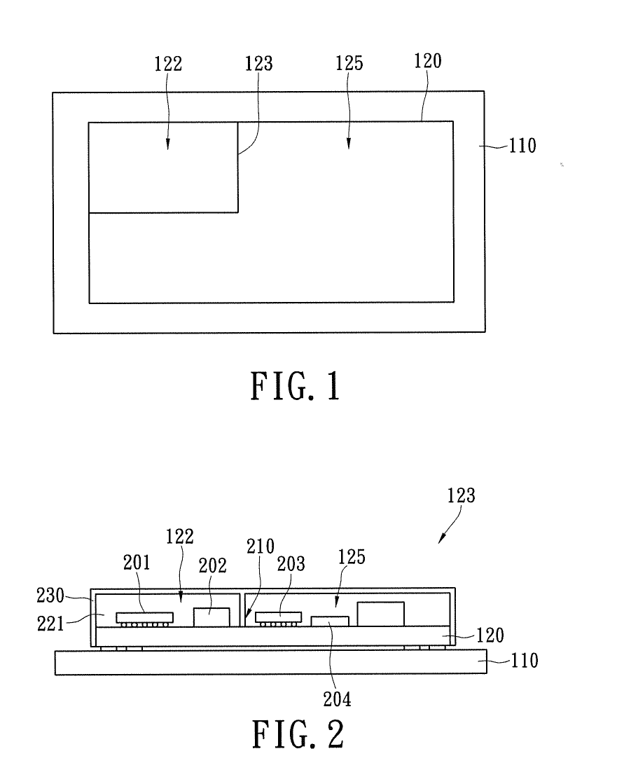

Please refer to FIG. 1, which shows a top view of an EMI shielding structure 123 on a printed circuit board 110. An IC substrate 120 is disposed onto the printed circuit board 110 and having separate chip areas 122 and 125 formed thereon. The chip areas 122 and 125 are separated by the EMI shielding structure 123 to reduce the EMI effect from affecting each other. The IC substrate 120, also called an IC carrier board, is equipped with internal circuitries for connecting to the printed circuit board 110. Formed by metal sputtering, the EMI shielding structure 123 provides a shielding structure that prevents the chips within the chip area 122 from EMI. Alternatively, the EMI shielding structure 123 can serve to prevent the chip areas 122 and 125 from interfering with one another due to EMI. The chip area 122 can be served for disposing the RF chip, such as the radio transceiver module, but is not restricted thereto.

Please refer to FIG. 2, which shows a schematic view of the EMI shielding structure 123 for the first embodiment of the instant disclosure. A RF chip 201 and a passive element 202, such as a 0402 type element, can be disposed in the chip area 122. Meanwhile, an active element 203 (such as a micro processor) and another passive element 204, such as 0201 type element, can be disposed in the chip area 125. However, the type of element for disposing in the chip areas 122 and 125 is not restricted. For the chip area 122, the EMI shielding structure 123 is mainly formed by at least one conductive contact 210, a covering layer 221, and a sputtered layer 230. The conductive contact 210 is formed at the perimeter of the chip area 122 to separate from the chip area 125. The conductive contact 210 can be disposed on the adjacent area between the chip areas 122 and 125 only, or around the chip area 122 completely. The instant embodiment does not restrict the location of the conductive contact 210. The conductive contact 210 is mainly for connecting to the above sputtered layer 230 and the IC substrate 120 to form the EMI shielding structure 123 that encloses the chip area 122. If the chip area 125 also requires the EMI shielding structure 123, both chip areas 122 and 125 can share the same conductive contact 210 at the adjacent area therebetween. Such configuration is illustrated in FIG. 2.

The covering layer 221 is an insulating layer formed during encapsulating the chip area 122 and 125 by using an encapsulating material (also called molding compound) such as thermosetting resin. The covering layer 221 is formed over both chip areas 122 and 125 completely. The sputtered layer 230 is a metal layer formed by the sputtering technique over the covering layer 221. The sputtered layer 230 is connected to the conductive contact 210 and further extends downwardly to the side surfaces of the IC substrate 120. The extended sputtered layer 230 is connected to the metal pads (not shown) of the side surfaces. The EMI shielding structure 123 would enclose the chip areas 122 and 125 completely to reduce the EMI. However, the EMI shielding structure 123 can also be disposed over one chip area only, such as the chip area 122 or 125.

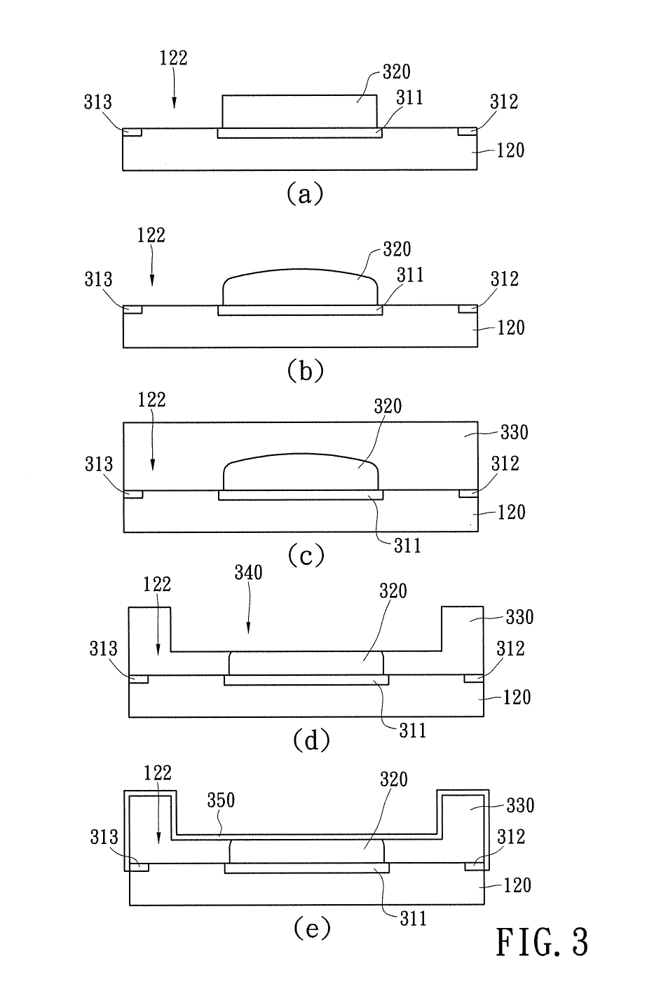

The EMI shielding structure 123 can be varied structurally. For example, the conductive contact 120 may be a metal pad, a solder ball, silver epoxy, etc. The fabrication step of the EMI shielding structure 123 will now be described. Please refer to FIG. 3, which shows a schematic view of forming the EMI shielding structure 123 for the first embodiment of the instant disclosure. As illustrated in FIG. 3A, a metal pad 311 and side metal pads 312 and 313 are first formed on the IC substrate 120. The material of the metal pad 311 and side metal pads 312 and 313 can be copper foil. In addition, the side metal pads 312 and 313 can be formed on the top surface or an inner-layer of the IC substrate 120. The instant embodiment does not restrict the locations of the side metal pads 312 and 313.

A solder block 320 is then disposed on the metal pad 311. The solder block 320 may also be replaced by a solder ball. Next, subjected to controlled heat, the method of reflow soldering is used to form the conductive contact 210, as shown in FIG. 3b. Followed by molding, epoxy is used for encapsulation in forming a covering layer 330, as shown in FIG. 3c. Then, laser scribing or mechanical routing technique is used to form a groove 340 on the covering layer 330 for exposing the solder block 320, as illustrated in FIG. 3d. Finally, sputtering technique is used to form a sputtered layer 350 on the covering layer 330 and the groove 340. The sputtered layer 350 would cover the required chip area for shielding and connect to the solder block 320 and the side metal pads 312 and 313, as shown in FIG. 3e.

### Second Embodiment

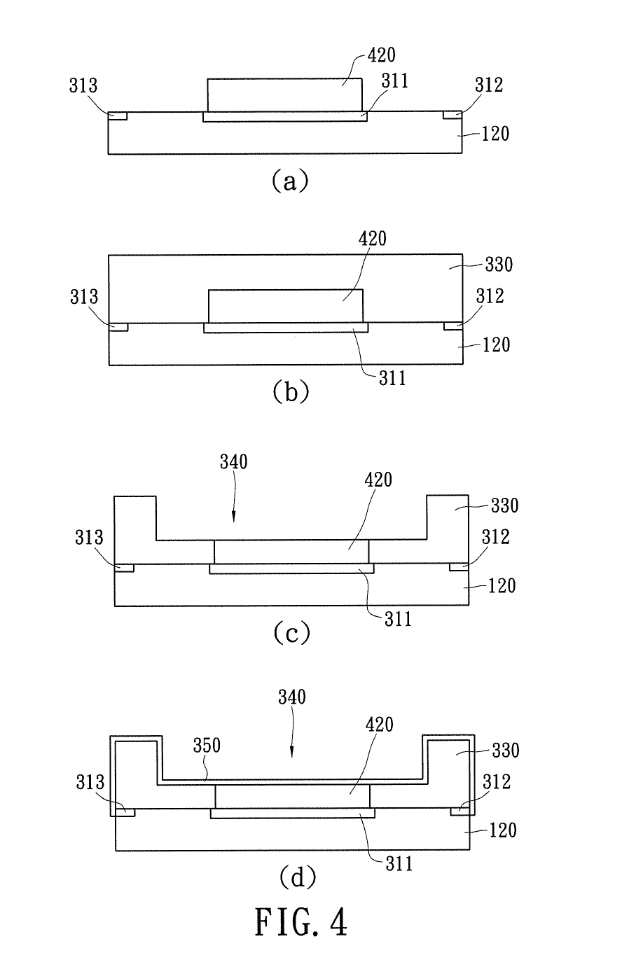

The aforementioned solder block 320 in the first embodiment may be replaced by the silver epoxy. Such replacement is illustrated in FIG. 4, which shows a schematic view of forming an EMI shielding structure for a second embodiment of the instant disclosure. As shown in FIG. 4a, the major difference between FIGS. 3 and 4 is that the solder block 320 is being replaced by a silver epoxy 420. The silver epoxy 420 does not require reflow soldering. Therefore, once the silver epoxy 420 is coated, molding can be performed directly as shown in FIG. 4b. Then, the covering layer 330 is grooved and sputtered as shown in FIGS. 4c and 4d. Other fabrication details are the same as in the first embodiment depicted by FIG. 3, and the description is omitted.

### Third Embodiment

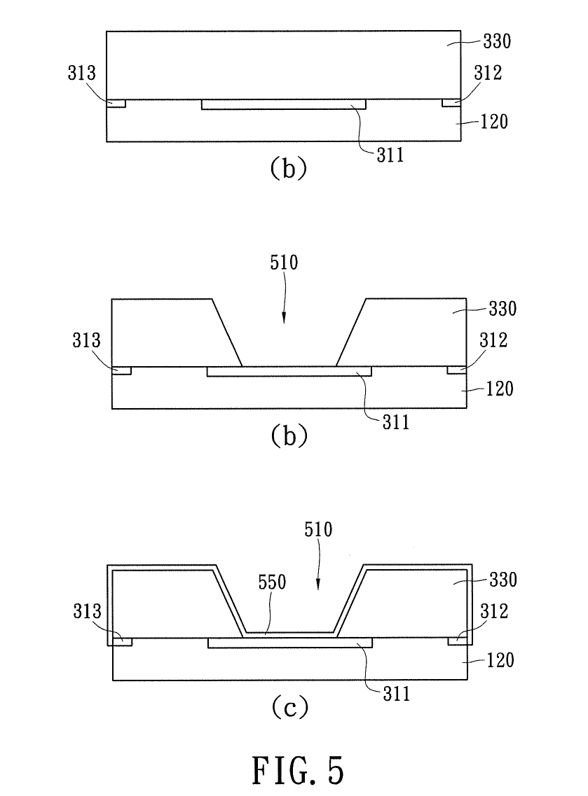

Please refer to FIG. 5, which shows a schematic view of forming an EMI shielding structure for a third embodiment of the instant disclosure. In the instant embodiment, the conductive contact 210 can be formed directly by the metal pad. Like before, the metal pad 311 and side metal pads 312 and 313 are pre-disposed on the IC substrate 120. Then, the IC substrate 120 is encapsulated directly in forming the covering layer 330, as shown in FIG. 5a. Next, laser scribing is used to form a groove 510 on the covering layer 330 to expose the metal pad 311 as illustrated in FIG. 5b. Lastly, a sputtered layer 550 is formed over the covering layer 330 and the groove 510 in forming the EMI shielding structure. The main difference between FIGS. 5 and 3 is that the metal pad 311 is used directly as the conductive contact 120. Other fabrication details are the same as in the above descriptions, and the details are omitted.

### Fourth Embodiment

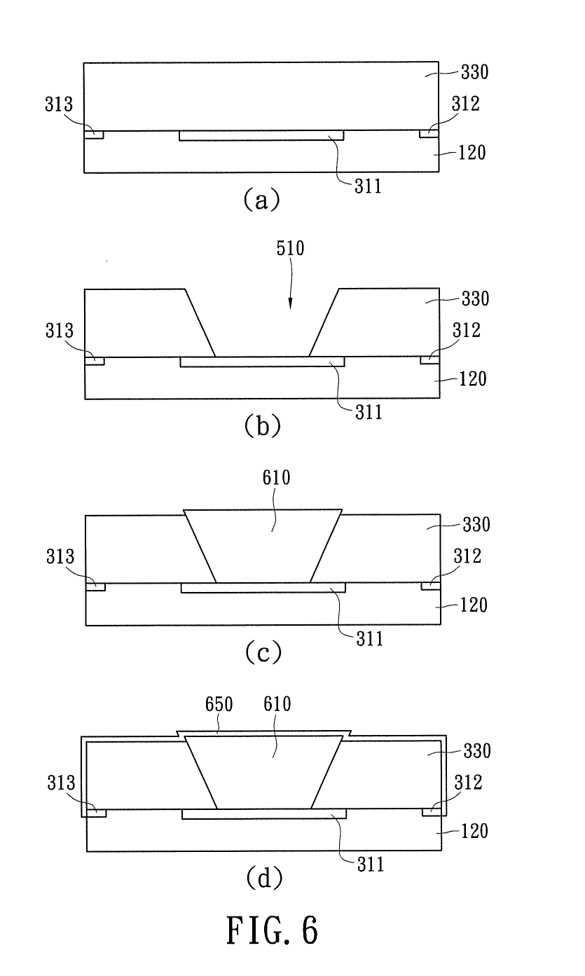

In aforementioned FIG. 5, the groove 510 can be filled with silver epoxy to increase electrical conductivity and improve production yield rate. Such method is illustrated in FIG. 6, which shows a schematic view of fabricating an EMI shielding structure for a fourth embodiment of the instant disclosure. The main difference between FIGS. 6 and 5 is that the groove 510 is filled with a silver epoxy 610, as shown in FIG. 6c. Next, sputtering process is performed to form a sputtered layer 650 as shown in FIG. 6d. The fabrication process depicted by FIGS. 6a and 6b are identical to FIGS. 5a and 5b respectively, therefore is not repeated herein.

### Fifth Embodiment

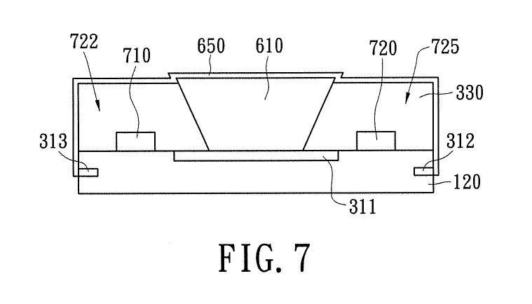

Please note, the side metal pads 312 and 313 can also be formed in the inner layer of the IC substrate 120, as illustrated in FIG. 7. Namely, FIG. 7 shows a schematic view of an EMI shielding structure for a fifth embodiment of the instant disclosure. For disposing chips 710 and 720, chip areas 722 and 725 are formed on opposite sides of the silver epoxy 610, respectively, wherein both chip areas 722 and 725 are enclosed by the sputtered layer 650 and silver epoxy 610. Since the chip areas 722 and 725 are divided from each other by being enclosed separately, the effect of EMI to each other can be reduced. The areas for disposing the chips from aforementioned embodiments, FIG. 3 to FIG. 6, are similar to that in FIG. 7. Based on above descriptions, any person who is skilled in the art can easily obtain other details, therefore these details will not be described herein.

In addition, the number of conductive contacts 120 can be varied depending on the design requirement. The arrangement of the conductive contacts 120 is also not restricted, which may form a fence shape with each conductive contact 120 being spaced apart from each other or grouped tightly with physical contact. Also, the metal pad 311 may be a metal wire that surrounds the side surfaces of the chip area 122. All of the solder blocks 320 are disposed on the same metal wire. The silver epoxy 420 is filled over the entire metal wire in forming a shielding layer. The aforementioned metal pad 311 or side metal pads 312 and 313 can be connected to ground via the metal wire of the substrate.

### Sixth Embodiment

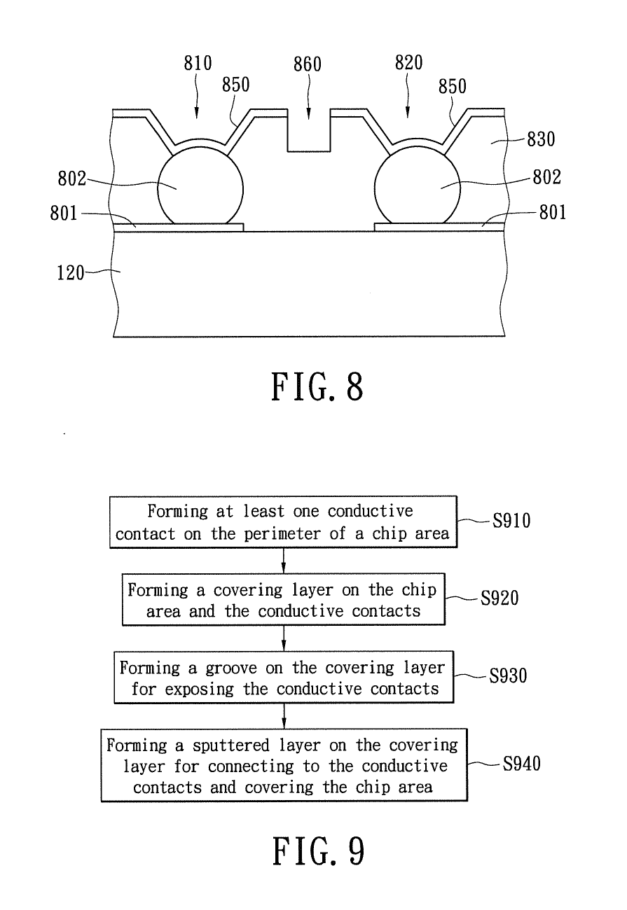

The two adjacent chip areas can share a common conductive contact or use separate conductive contact individually. Such configuration is shown in FIG. 8, which illustrates an EMI shielding structure for a sixth embodiment of the instant disclosure. Solder balls 802 and metal pads 801 are used as conductive contacts 810 and 820. A covering layer 830 covers the IC substrate 120 and is grooved for exposing the conductive contacts 810 and 820. A sputtered layer 850 is formed on the covering layer 830 and connecting the conductive contacts 810 and 820. Notably, laser scribing or mechanical routing is implemented in forming a separating groove 860, which is in between the conductive contacts 810 and 820 to split the sputtered layer 850. In other words, two independent EMI shielding structures are formed on the IC substrate 120 for covering different chip areas.

### Seventh Embodiment

A fabrication method of the EMI shielding structure for the IC substrate can be derived based on preceding descriptions. In particular, FIG. 9 shows a flow diagram for the fabrication method of the EMI shielding structure on the IC substrate. For the first step, denoted by step S910, conductive contacts are formed on the perimeter of the chip area. Then, for step S920, the covering layer is formed on the chip area and the conductive contacts. Next, in step S930, the groove is formed on the covering layer for exposing the conductive contacts. Lastly, for step S940, the sputtered layer is formed on the covering layer for connecting to the conductive contacts and enclosing the chip area. Other details associated with the fabrication method of the EMI shielding structure can be referred to the aforementioned first thru fifth embodiment, thus will not be described again herein.

Notably, for the aforementioned embodiments, the sputtered layer can be formed by metal sputtering or spray coating with conductive varnish. The conductive varnish can be silver or copper varnish. However, the formation of the sputtered layer is not restricted to sputtering technique only for the instant disclosure.

Based on the above, the EMI shielding structure of the instant disclosure can be formed directly on the IC substrate, wherein the RF chip can be prevented from the EMI interferences effectively. In addition, the EMI shielding structure can be miniaturized and reduce the fabrication cost. Also, current fabrication technologies can be applied directly to perform the fabrication. Thus, the EMI shielding structure has significant industrial applicability.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. An electromagnetic interference (EMI) shielding structure for integrated circuit (IC) substrate having a chip area, comprising:
a plurality of conductive contacts formed on a perimeter of the chip area;
a covering layer formed on the conductive contacts and over the chip area, wherein a groove is formed on the covering layer for exposing the conductive contacts; and
a sputtered layer formed on the covering layer and connected to the conductive contacts.

2. The EMI shielding structure of claim 1, wherein the conductive contacts are metal pads formed on the IC substrate.

3. The EMI shielding structure of claim 1, wherein each conductive contact comprises:
a metal pad formed on the IC substrate; and
a solder ball disposed on the metal pad.

4. The EMI shielding structure of claim 1, wherein each conductive contact comprises:
a metal pad formed on the IC substrate; and
a silver epoxy filled onto the metal pad.

5. The EMI shielding structure of claim 1, wherein the covering layer is made of thermosetting epoxy resin.

6. The EMI shielding structure of claim 1, further comprising a side metal pad formed at a side of the IC substrate, wherein the sputtered layer extends downwardly to the side of the IC substrate in connecting to the side metal pad.

7. The EMI shielding structure of claim 1, wherein the sputtered layer is formed by metal sputtering or spray coating with conductive varnish, wherein conductive varnish is selected from a group consisting of silver and copper varnish.

8. A fabrication method of an EMI shielding structure for IC substrate, comprising:
forming at least one conductive contact at a perimeter of a chip area defined on the IC substrate;
forming a covering layer on the chip area and the conductive contact;
forming a groove on the covering layer for exposing the conductive contacts; and
forming a sputtered layer on the covering layer for connecting to the conductive contacts and covering the chip area.

9. The fabrication method of claim 8, wherein the step of forming the conductive contacts comprising:
forming at least one metal pad on the IC substrate.

10. The fabrication method of claim 9, wherein the step of forming the conductive contacts further comprising:
disposing a solder ball on each metal pad.

11. The fabrication method of claim 9, wherein the step of forming the conductive contacts further comprising:
filling silver epoxies on the metal pads.

12. The fabrication method of claim 8, wherein the step of forming the groove for exposing the conductive contacts further comprising:
cutting the covering layer with laser scribing.

13. The fabrication method of claim 8, wherein the step of forming the groove for exposing the conductive contacts further comprising:
cutting the covering layer with mechanical routing.

14. The fabrication method of claim 8, further comprising:
forming a side metal pad on a side of the IC substrate, wherein the sputtered layer extends downwardly to the side of the IC substrate and connects to the side metal pad.

15. The fabrication method of claim 8, wherein the sputtered layer is formed by metal sputtering or spray coating with conductive varnish, wherein conductive varnish is selected from a group consisting of silver and copper varnish.
